(19) United States
(12) Patent Application Publication
(10) Pub. No.: US 2019/0194809 A1
(43) Pub. Date: Jun. 27, 2019

(54) APPARATUS AND METHODS FOR ATOMIC LAYER DEPOSITION

(71) Applicant: PICOSUN OY, Espoo (FI)

(72) Inventors: Niklas HOLM, Espoo (FI); Juhana KOSTAMO, Espoo (FI); Timo MALINEN, Espoo (FI); Marko PUDAS, Espoo (FI)

(21) Appl. No.: 16/329,788

(22) PCT Filed: Sep. 16, 2016
(86) PCT No.: PCT/FI2016/050644

§ 371 Date: Mar. 1, 2019

(51) Int. Cl. C23C 16/455; C23C 16/458; C23C 16/46; C23C 16/44

(52) U.S. Cl. CPC C23C 16/45544; C23C 16/4584; C23C 16/52; C23C 16/4412; C23C 16/45502; C23C 16/463

(57) ABSTRACT

A system and method for atomic layer deposition, ALD, where an actuator arrangement is configured to receive a batch of substrates and transfer the substrates through a first load-lock horizontally into a vacuum chamber, and to lower the substrates within the vacuum chamber into a reaction chamber thus closing the reaction chamber with a lid.

### FIELD

The aspects of the disclosed embodiments generally relate to Atomic Layer Deposition (ALD). More particularly, but not exclusively, the aspects of the disclosed embodiments relate to a system for Atomic Layer Deposition (ALD).

### BACKGROUND

This section illustrates useful background information without admission of any technique described herein representative of the state of the art.

Batch processing of substrates to be coated with Atomic Layer Deposition (ALD) is preferably carried out with a system providing ease of use, high quality coating and optimized throughput.

Prior art Atomic Layer Deposition systems that have sought to provide processing with automated substrate handling for high throughput do exist. Somewhat related systems have been disclosed for example in following publications.

US20070295274 discloses a batch processing platform used for ALD or CVD processing configured for high throughput and minimal footprint. In one embodiment, the processing platform comprises an atmospheric transfer region, at least one batch processing chamber with a buffer chamber and staging platform, and a transfer robot disposed in the transfer region wherein the transfer robot has at least one substrate transfer arm that comprises multiple substrate handling blades.

EP2249379 discloses a batch-type ALD apparatus that includes: a chamber that can be kept in a vacuum state; a substrate support member, disposed in the chamber, supporting a plurality of substrates to be stacked one onto another with a predetermined pitch; a substrate movement device moving the substrate support member upward or downward; a gas spray device continuously spraying a gas in a direction parallel to the extending direction of each of the substrates stacked in the substrate support member; and a gas discharge device, disposed in an opposite side of the chamber to the gas spray device, sucking and evacuating the gas sprayed from the gas spray device.

U.S. Pat. No. 4,582,720 discloses an apparatus for forming a non single-crystal layer, comprising a substrate introducing chamber, a reaction chamber and a substrate removing chamber sequentially arranged with a shutter between adjacent ones of them. One or more substrates are mounted on a holder with their surfaces lying in vertical planes and carried into the substrate introducing chamber, the reaction chamber and the substrate removing chamber one after another.

US20010013312 discloses an apparatus for growing thin films onto the surface of a substrate by exposing the substrate to alternately repeated surface reactions of vapor-phase reactants. The apparatus comprises at least one process chamber having a tightly sealable structure, at least one reaction chamber having a structure suitable for adapting into the interior of said process chamber and comprising a reaction space of which at least a portion is movable, infeed means connectable to said reaction space for feeding said reactants into said reaction space, and outfeed means connectable to said reaction space for discharging excess reactants and reaction gases from said reaction space, and at least one substrate adapted into said reaction space.

US20100028122 discloses an apparatus in which a plurality of ALD reactors are placed in a pattern in relation to each other, each ALD reactor being figured to receive a batch of substrates for ALD processing, and each ALD reactor comprising a reaction chamber accessible from the top. A plurality of loading sequences is performed with a loading robot.

WO2014080067 discloses an apparatus for loading a plurality of substrates into a substrate holder in a loading chamber of a deposition reactor to form a vertical stack of horizontally oriented substrates within said substrate holder, for turning the substrate holder to form a horizontal stack of vertically oriented substrates, and for lowering the substrate holder into a reaction chamber of the deposition reactor for deposition.

It is an object of embodiments of the present disclosure to provide an improved Atomic Layer Deposition system with high throughput batch processing.

### SUMMARY

According to a first example aspect of the disclosed embodiments there is provided a system for atomic layer deposition, ALD, comprising:

a reaction chamber element comprising

a vacuum chamber;

a reaction chamber inside the vacuum chamber; and

a gas inlet arrangement and a foreline configured to provide a horizontal flow of gas in the reaction chamber;

an actuator arrangement comprising a reaction chamber lid, and

at least a first load-lock element comprising a first load-lock,
the actuator arrangement being configured to receive a substrate or a batch of substrates to be processed and transfer the substrate or the batch of substrates through the first load-lock horizontally into the vacuum chamber,
the actuator arrangement being further configured to lower the substrate or the batch of substrates within the vacuum chamber into the reaction chamber thus closing the reaction chamber with the lid.

The substrate or batch of substrates include, for example: wafers, glass, silicon, metal or polymer substrates, printed circuit board (PCB) substrates, and 3D substrates.

In certain example embodiments, there is provided a flow-through reaction chamber (or cross-flow reactor) in which gases within the reaction chamber travel across the reaction chamber from the gas inlet arrangement to the foreline along the substrate surfaces without (substantially) colliding with transverse structures.

In certain example embodiments, the substrates are oriented in the direction of the gas flow within the reaction chamber. In certain example embodiments, the surface of the substrate (to be exposed to atomic layer deposition) within the reaction chamber is in parallel to the direction of precursor gas flow within the reaction chamber.

In certain example embodiments, the substrates in the batch of substrates are oriented horizontally to form a vertical stack horizontally oriented substrates. In certain example embodiments, the substrates in the batch of substrates are oriented vertically to form a horizontal stack of vertically oriented substrates.

In certain example embodiments, the gas inlet arrangement and foreline are located at different sides of the reaction chamber. In certain example embodiments, the gas inlet arrangement and foreline are located at opposite sides of the reaction chamber.

In certain example embodiments, the actuator arrangement receives the substrate or batch of substrates in the load-lock element or load-lock.

In certain example embodiments, the system further comprises a loader configured to transfer the substrate or batch of substrates into the load-lock element or load-lock.

In certain example embodiments, the actuator arrangement comprises a first horizontal actuator in the first load-lock element and a vertical actuator in the reaction chamber element, the first horizontal actuator being configured to receive the substrate or the batch of substrates and transfer the substrate or the batch of substrates through the first load-lock horizontally into the vacuum chamber, and the vertical actuator being configured to receive the substrate or the batch of substrates from the first horizontal actuator and lower the substrate or the batch of substrates into the reaction chamber. In certain example embodiment, the vertical actuator is configured to lift a substrate holder carrying the substrate or batch of substrates to release the grip of the horizontal actuator on the substrate holder.

In certain example embodiments, the substrate or batch of substrates is unloaded through an opening other than through which the substrate or batch of substrates is loaded.

In certain example embodiments, the system comprises a second load-lock element comprising a second load-lock.

In certain example embodiments, the system comprises a first loading valve between the first load-lock and a loading opening of the vacuum chamber.

In certain example embodiments, the system comprises a first loading valve between the first load-lock and a loading opening of the vacuum chamber and a second loading valve between the second load-lock and a loading opening of the vacuum chamber.

In certain example embodiments, the actuator arrangement comprises a second horizontal actuator in the second load-lock element. In certain example embodiments, the second horizontal actuator is configured to receive the substrate or the batch of substrates from the vertical actuator.

In certain example embodiments, the first load-lock forms a confined closed volume and comprises a part of the actuator arrangement.

The actuator arrangement may be an actuator apparatus having parts both in the first load-lock element and in the reaction chamber element (as well as in the second load-lock element, in certain embodiments). In certain example embodiments, the system is configured to provide automated substrate handling. In certain example embodiments, the automated substrate handling comprises transferring the substrate or the batch of substrates automatically (without human interaction) from the first load-lock element or load-lock into the reaction chamber of the reaction chamber element. In certain example embodiments, the automated substrate handling further comprises transferring the substrate or the batch of substrates automatically (without human interaction) from the reaction chamber to the first or second load-lock element or load-lock. In certain example embodiments, the automated substrate handling comprises transferring the substrate or the batch of substrates automatically (without human interaction) from a loading module into the first load-lock element or load-lock.

In certain example embodiments, the system comprises a loading module, such as an equipment front end module, and/or a loading robot connected to the first load-lock element.

In certain example embodiments, the vacuum chamber comprises at least one shield element configured to be moved in front of at least one loading opening of the vacuum chamber.

In certain example embodiments, the at least one shield element is configured to be moved with actuators and/or in synchronization with the opening and closing of the loading valves.

In certain example embodiments, the system comprises at least one residual gas analyzer element comprising a residual gas analyzer, RGA, and connected to the first and/or second load-lock element and/or foreline. In certain example embodiments, the system is configured to control the process timing based on information received from the RGA. The process timing may, for example, refer to the pre-processing time of the substrate or batch of substrates in load-lock or timing a starting point of a precursor pulse.

In certain example embodiments, the RGA is configured to analyze the out-coming gas from the reaction chamber in order to let the user adjust or to automatically adjust cleaning and/or reactants in-feed and/or pulsing sequence timing in the reaction chamber. In certain example embodiments, the RGA is configured detect a leak in the system.

In certain example embodiments, the reaction chamber comprises a removable or fixed flow guide element. In certain example embodiments, the flow guide element comprises a plurality of apertures. In certain example embodiments, the flow guide element is attached to a fixed or removable frame. In certain example elements, the flow guide element is located at a gas inlet side of the reaction chamber. In certain example embodiments, the reaction chamber comprises a removable or fixed flow guide element in an exhaust side of the reaction chamber. In certain example embodiments the reaction chamber comprises both flow guides: one at the gas inlet side and one in the foreline (exhaust) side. In certain example embodiments, there is provided a controlled foreline flow affecting the pressure and flow within the reaction chamber element. The flow guide element(s) provide a controlled effect on gas flow and pressure within the reaction chamber element thereby improving the possibility to optimize the uniformity of coating.

In certain example embodiments, the system comprises at least one heated source element connected to the reaction chamber element.

In certain example embodiments, the system comprises source inlets traveling inside the vacuum chamber. In certain example embodiments, the system comprises a temperature stabilization arrangement, comprising reaction chamber source inlet lines traveling a detour inside the vacuum chamber for stabilizing the temperature of precursor chemicals within the inlet lines. This is in contrast to having the reaction chamber source inlet lines traveling the substantially shortest route from the outside of the vacuum chamber to the reaction chamber.

In certain example embodiments, the foreline travels inside the vacuum chamber. The foreline in certain example embodiments takes a detour on its way to the outside of the vacuum chamber to keep the foreline hot (close to the temperature prevailing within the vacuum chamber) for preventing chemical absorption to it. A hot foreline also increases chemical reactions so as to decrease the probability of chemicals diffusing back to the reaction chamber.

In certain example embodiments, the system comprises a cassette for holding the substrate or the batch of substrates to be processed. In certain example embodiments, the system comprises a cassette for holding the substrate or the batch of substrates to be processed horizontally. In certain example embodiments, a substrate is handled without a cassette or similar.

In certain example embodiment, the substrate or batch of substrates is handled within the load lock and reaction chamber elements by carrying the substrate or batch of substrates with a substrate holder. The substrate holder may be carry pure substrates. In certain example embodiments, the substrate holder comprises one or more underlays for the substrate(s) to lie on. Alternatively, the substrate holder carries substrates residing in another substrate holder (e.g., a cassette). The holder may be flipped within the vacuum chamber to change the orientation of the substrate of batch of substrates from vertical to horizontal (or horizontal to vertical).

In certain example embodiments, the system comprises a rotator configured to rotate the substrate or the batch of substrates within the reaction chamber. Accordingly, in certain example embodiments, the system is configured to rotate the substrate or batch of substrates within the reaction chamber during atomic layer processing. In certain example embodiments, the substrate holder carrying the substrate or batch of substrates is a rotating substrate holder.

In certain example embodiments, the system is configured to heat the substrate or batch of substrates in the first load lock element. In certain example embodiments, the system is configured to cool the substrate or batch of substrates (processed by ALD) in the first or second load lock element. In certain example embodiments, the system is configured to heat or cool the substrate or batch of substrates in at least one of the first and second load lock element.

In certain example embodiments, the system is configured to pump down the load-lock pressure below the pressure used in the reaction chamber.

In certain example embodiments, the system is configured to measure gases coming from the substrate or the batch of substrates in the load-lock.

According to a second example aspect of the invention there is provided a method of operating a system for atomic layer deposition, ALD, comprising:
transferring a substrate or a batch of substrates into a first load-lock;
transferring the substrate or the batch of substrates further from the first load-lock via a first loading valve and a loading opening horizontally into a vacuum chamber;
receiving the substrate or the batch of substrates in the vacuum chamber and lowering the substrate or the batch of substrates into a reaction chamber inside the vacuum chamber, the act of lowering closing the reaction chamber with a lid;
carrying out atomic layer deposition in the reaction chamber;
raising the substrate or the batch of substrates from the reaction chamber;
receiving the substrate or the batch of substrates from the reaction chamber and transferring the substrate or the batch of substrates via the first or a second loading valve and a loading opening from the vacuum chamber into the first or a second load-lock.

In certain example embodiments, the method comprises moving at least one shield element in front of the at least one load opening, respectively, before the atomic layer deposition; and removing the at least one shield element from front of the at least one load opening, respectively, after the atomic layer deposition.

In certain example embodiments, the method comprises carrying the substrate or batch of substrates in a cassette (or substrate holder) within the system. In certain example embodiments, a single substrate or substrates is/are handled without a cassette or similar.

In certain example embodiments, the method comprises loading a system of substrates or the batch of substrates into a cassette before transferring to the load-lock. In certain example embodiments, the method comprises loading a system of substrates or the batch of substrates from the load-lock.

In certain example embodiments, the method provides gas in-feed within the reaction chamber in a horizontal direction. In certain example embodiments, the gas in-feed within the reaction chamber is transverse with respect to the horizontal transfer direction of the substrate(s). In certain example embodiments, the gas in-feed within the reaction chamber is parallel with the horizontal transfer direction of the substrate(s).

In certain example embodiments, the pressure or flow speed of the gas or gases in the reaction chamber is adjusted by controlling of incoming gas flow and/or outgoing gas flow in foreline.

In certain example embodiments, one or more surfaces forming part of the reaction chamber and being protected by metal oxide are used so as to improve chemical durability and/or to improve heat reflection inwards.

According to a third example aspect there is provided a method of operating a system for atomic layer deposition, ALD, comprising:
providing a shield element on the outside of a reaction chamber but on the inside of a vacuum chamber;
moving the shield element within the vacuum chamber in front of a loading opening of the vacuum chamber; and
carrying out atomic layer deposition in the reaction chamber inside the vacuum chamber.

According to a fourth example aspect there is provided an apparatus for atomic layer deposition, ALD, comprising:
a reaction chamber inside a vacuum chamber; and
a shield element on the outside of a reaction chamber but on the inside of the vacuum chamber, the apparatus being configured to
move the shield element within the vacuum chamber in front of a loading opening of the vacuum chamber; and
carry out atomic layer deposition in the reaction chamber inside the vacuum chamber.

According to a fifth example aspect there is provided a method of operating a system for atomic layer deposition, ALD, comprising:
providing a reaction chamber inside a vacuum chamber, and a foreline leading from the reaction chamber to the outside of the vacuum chamber, the method comprising:
maintaining heat within the foreline by allowing the foreline to take a detour within the vacuum chamber on its way to the outside of the vacuum chamber.

According to a sixth example aspect there is provided an apparatus for atomic layer deposition, ALD, comprising:
a reaction chamber inside a vacuum chamber; and
a foreline taking a detour on its way from the reaction chamber to the outside of the vacuum chamber.

According to a seventh example aspect there is provided a method of operating a system for atomic layer deposition, ALD, comprising:
providing a reaction chamber inside a vacuum chamber;
carrying out atomic layer deposition on a sensitive substrate or a batch of sensitive substrates in the reaction chamber;
transferring, after the deposition, the substrate or a batch of sensitive substrates via the vacuum chamber to a load lock connected to the vacuum chamber; and
cooling the sensitive substrate or a batch of sensitive substrates within the load lock in vacuum.

Sensitive substrates include, for example, glass, silicon, PCB and polymer substrates. In a further example embodiment, a metal substrate or a batch of metal substrates are cooled within the load lock in vacuum.

According to an eighth example aspect there is provided an apparatus for atomic layer deposition, ALD, comprising:
a reaction chamber element comprising a reaction chamber inside a vacuum chamber;
a foreline connected to the reaction chamber and configured to lead gases out from the reaction chamber;
a residual gas analyzer connected to the foreline; and
a control element connected to the reaction chamber element and to the residual gas analyzer, wherein
the control element is configured to control process timing by received information measured by the residual gas analyzer.

In certain example embodiments, the measured information comprises moisture level of gas coming out from the reaction chamber. In certain example embodiments, the measured information comprises information on the amount of reaction products or by-products coming out from the reaction chamber. In certain example embodiments, the control unit is configured to prevent the commencement of a precursor pulse if the received information exceeds a pre-defined limit. In certain example embodiments, the control unit is configured to ensure there is chemical fed into the reaction chamber, thus verifying the proper functioning of the reactor.

Cooling in vacuum minimizes the risk of damaging the deposited substrate(s). In certain example embodiments, the vacuum pressure used in the load lock when cooling is the same as the vacuum pressure used in the vacuum chamber.

Different non-binding example aspects and embodiments of the present invention have been illustrated in the foregoing. The above embodiments are used merely to explain selected aspects or steps that may be utilized in implementations of the present disclosure. Some embodiments may be presented only with reference to certain example aspects of the invention. It should be appreciated that corresponding embodiments may apply to other example aspects as well. Any appropriate combinations of the embodiments may be formed.

### BRIEF DESCRIPTION OF THE DRAWINGS

The aspects of the disclosed embodiments will now be described, by way of example only, with reference to the accompanying drawings, in which:

FIG. 1 shows a schematic top view of an Atomic Layer Deposition (ALD) system according to an embodiment of the present disclosure;

FIG. 2 shows a schematic side view of an Atomic Layer Deposition (ALD) system according to an embodiment of the present disclosure;

FIG. 3 shows a schematic view of a reaction chamber element of an Atomic Layer Deposition (ALD) system according to an embodiment of the present disclosure;

FIG. 4 shows a schematic view into a reaction chamber element of an Atomic Layer Deposition (ALD) system according to an embodiment of the present disclosure;

FIG. 5 shows a schematic view into a reaction chamber element of an Atomic Layer Deposition (ALD) system according to an embodiment of the present disclosure;

FIG. 6 shows a schematic view into a reaction chamber element of an Atomic Layer Deposition (ALD) system according to an embodiment of the present disclosure;

FIG. 7 shows a schematic view into a reaction chamber element of an Atomic Layer Deposition (ALD) system according to an embodiment of the present disclosure;

FIG. 8 shows a schematic side view of a reaction chamber of an Atomic Layer Deposition (ALD) system according to an embodiment of the present disclosure;

FIG. 9 shows a schematic principle view of loading a reaction chamber element of an Atomic Layer Deposition (ALD) system according to an embodiment of the present disclosure;

FIG. 10 shows a schematic top view of an Atomic Layer Deposition (ALD) system according to yet another embodiment of the present disclosure;

FIG. 11 shows a flow chart of method of operating an Atomic Layer Deposition (ALD) system according to an embodiment of the present disclosure;

FIG. 12 shows a schematic principle view of loading a reaction chamber element of an Atomic Layer Deposition (ALD) system according to an alternative embodiment of the present disclosure; and

FIG. 13 shows a schematic view into a reaction chamber element of an Atomic Layer Deposition (ALD) system according to yet another embodiment of the present disclosure.

### DETAILED DESCRIPTION

In the following description, Atomic Layer Deposition (ALD) technology is used as an example. The basics of an ALD growth mechanism are known to a skilled person. ALD is a special chemical deposition method based on the sequential introduction of at least two reactive precursor species to at least one substrate. It is to be understood, however, that one of these reactive precursors can be substituted by energy when using photo-enhanced ALD or PEALD, leading to single precursor ALD processes. Thin films grown by ALD are dense, pinhole free and have uniform thickness.

The at least one substrate is typically exposed to temporally separated precursor pulses in a reaction vessel to deposit material on the substrate surfaces by sequential self-saturating surface reactions. In the context of this application, the term ALD comprises all applicable ALD based techniques and any equivalent or closely related technologies, such as, for example the following ALD sub-types: MLD (Molecular Layer Deposition) PEALD (Plasma Enhanced Atomic Layer Deposition) and photo-enhanced Atomic Layer Deposition (known also as flash enhanced ALD).

A basic ALD deposition cycle consists of four sequential steps: pulse A, purge A, pulse B and purge B. Pulse A consists of a first precursor vapor and pulse B of another precursor vapor. Inactive gas and a vacuum pump are typically used for purging gaseous reaction by-products and the residual reactant molecules from the reaction space during purge A and purge B. A deposition sequence comprises at least one deposition cycle. Deposition cycles are repeated until the deposition sequence has produced a thin film or coating of desired thickness. Deposition cycles can also be either simpler or more complex. For example, the cycles can include three or more reactant vapor pulses separated by purging steps, or certain purge steps can be omitted. All these deposition cycles form a timed deposition sequence that is controlled by a logic unit or a microprocessor.

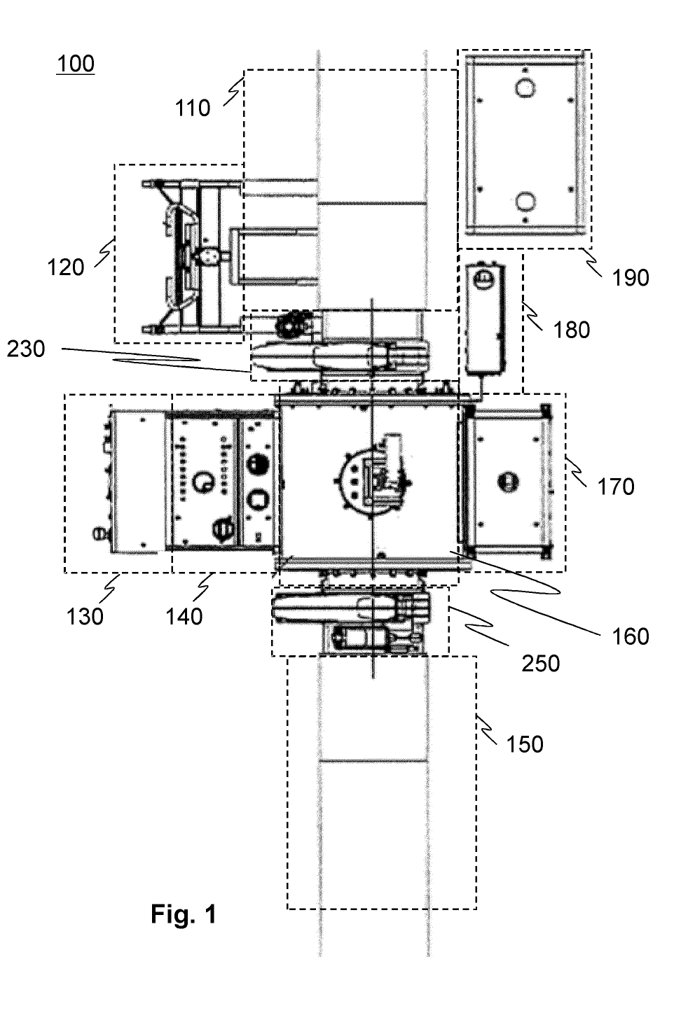

FIG. 1 shows a schematic top view of an Atomic Layer Deposition (ALD) system 100 according to an embodiment of the invention. The ALD system 100 comprises a first load-lock element 110 configured to receive substrates to be loaded into the system for deposition. In an embodiment, the substrates, are placed into substrate holders, or cassettes, for loading, and the cassettes are handled by a cassette element 120 comprised in the ALD system 100. In an embodiment, the cassette element 120 is replaced by a man loading the cassettes into the load-lock element 110. Alternatively, substrates are loaded into a substrate holder, or cassette, in the load-lock element 110. In an embodiment, the first load-lock element is also configured to receive substrates to be unloaded from the system after the deposition.

The ALD system 100 further comprises a reaction chamber element 160 comprising a single part vacuum chamber. The first load-lock element 110 is connected to the reaction chamber element 160 via a first gate valve element 230 as described hereinafter. The system 100 further comprises a control element 130, a chemical source element 140 comprising liquid and gas sources and a heated chemical source element 170. In a further embodiment, the ALD system 100 comprises several reaction chamber elements in a row, in an embodiment connected with further gate valve elements. Although the chemical sources are depicted on specific sides in FIG. 1, in an embodiment the location of the source element 140 and the heated source element 170 is chosen in a different manner according to the situation.

The ALD system 100 further comprises, in an embodiment, a second load-lock element 150 configured to receive substrates unloaded after the deposition. The second load-lock element is connected to the reaction chamber element 160 via a second gate valve element 250 as described hereinafter.

The ALD system 100 further comprises, a residual gas analyzer element comprising a residual gas analyzer (RGA) 180 connected to the first and/or second load-lock element, and/or to a foreline before a particle trap 190.

It is to be noted that the elements of the ALD system 100 described hereinbefore and hereinafter are individually detachable from the system, thus providing ease of access in case of for example periodical maintenance.

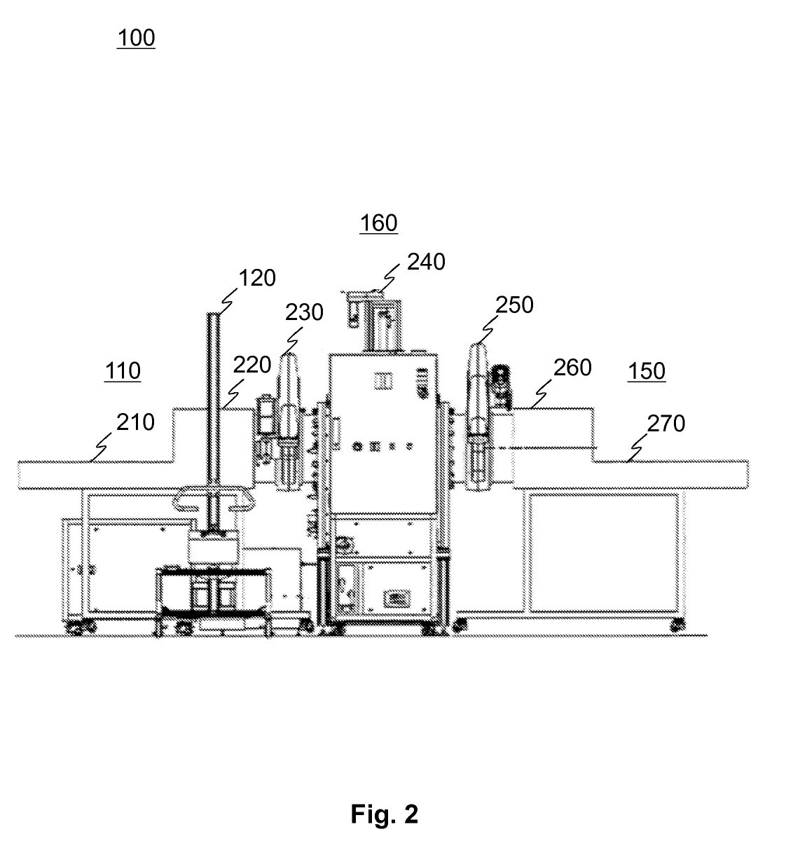

FIG. 2 shows a schematic side view of an Atomic Layer Deposition (ALD) system according to an embodiment of the invention. The system shown in FIG. 2 comprises the elements as described hereinbefore with reference to FIG. 1.

The first load-lock element 110 comprises a first horizontal actuator 210 configured to transfer a substrate holder (or cassette) loaded with substrates to be processed into the reaction chamber element 160. In an embodiment, the first horizontal actuator comprises a linear actuator. In this description, the terms cassette and substrate holder are used interchangeably. The cassette in which substrates are loaded into the load lock element 110 is not necessarily the same substrate holder which carries the substrate(s) further within the system.

The first load-lock element further comprises a first load-lock 220. The cassettes/holders holding the substrates are loaded into the first load-lock using the cassette element 120. The first load-lock 220 comprises a door through which the cassette of substrates is inserted. In alternative embodiments, a planar substrate or a 3D substrate or a batch of substrates from a cassette (or another substrate holder) are loaded into a substrate holder waiting within the first load lock 220. Accordingly, the substrate or batch of substrates can be loaded together with cassette already carrying the substrate(s), or from one cassette into a second cassette. In an embodiment, the first load-lock further comprises a circulation temperature controller configured to hold the load-lock at a desired temperature using convection at atmospheric pressure.

In an embodiment, the load-lock is configured to perform one or more of the following:
to heat the substrate(s);
to cool the substrate(s);
to evacuate the load-lock into the vacuum of an intermediate space (i.e., a space in between a vacuum chamber wall and a reaction chamber wall);
to evacuate the load-lock into a vacuum with a pressure lower than that of the intermediate space and ALD reaction conditions, for example, 50 μbar;
to purge the substrate(s) with a continuous gas flow in order to even its/their temperature;
to purge the substrate(s) with a continuous gas flow in order to dry and/or purify it/them;
to even heat within the load-lock, for example, by a fan operating within the load-lock.
analyze the out-coming gases, with the aid of RGA 180.

In an embodiment, the load-lock comprises an inert gas atmosphere. In a further embodiment, the load-lock comprises a variable state of vacuum to affect heating and degassing. In an embodiment, the load-lock is heated by thermal or electromagnetic radiation, such as microwave.

The first load-lock 220 comprises, in an embodiment, a pump, for example a turbomolecular pump, configured to evacuate the load-lock. It is to be noted that the first load-lock 220 comprises for example gas connections, electrical connections and further components in a manner known in the field.

The first load-lock element 110 further comprises a first gate valve element 230, or a loading valve, configured to connect the first load-lock 220 to the reaction chamber element 160. The first loading valve 230 is configured to be opened in order to allow the first horizontal actuator 210 to transfer a cassette holding the substrates to be processed into the reaction chamber element 160 and configured to be closed in order to close the reaction chamber element 160. In an embodiment, the first load-lock and the first loading valve are also configured for unloading the reaction chamber element 160.

The reaction chamber element 160 comprises a vertical actuator 240 configured to receive a cassette of substrates to be processed from the first horizontal actuator and to lower the cassette into a reaction chamber on the lower part of the reaction chamber element 160 and to lift the cassette therefrom.

The second load-lock element 150 of the ALD system 100 comprises components similar to those of the first load-lock element 110. The second load-lock element 150 comprises a second load-lock 260 having similar properties and structures as the first load-lock 220 as hereinbefore described. The second load-lock element further comprises a second horizontal actuator 270 configured to transfer a cassette that has been processed from the reaction chamber element 160 into the second load-lock 260.

The second load-lock element 150 further comprises a second gate valve element 250, or a second loading valve, configured to connect the second load-lock 260 to the reaction chamber element 160. The second loading valve 250 is configured to be opened in order to allow a second horizontal actuator 270 to transfer a cassette holding the substrates that have been processed from the reaction chamber element 160 and configured to be closed in order to close the reaction chamber element 160.

The actuators 210, 240 (or actuators 210, 240 and 270) form an actuator arrangement. In an embodiment, the actuator arrangement is configured to move the substrates horizontally and vertically to their position in the reaction chamber.

According to an embodiment, in normal operation, the substrates, or samples in a cassette are loaded into the load-lock 220 (or 260) in ambient pressure and subsequently a door of the load-lock is closed. Depending on the program in used, the load-lock is evacuated and vented to a controlled temperature and pressure, as programmed for the loaded substrates. An example of the loading comprises: Evacuation of ambient gases down to 1 μbar (1*10⁻⁶ bar) vacuum, venting the load-lock with inert gas to a preselected pressure, heating the substrates while measuring the out-coming gases with the RGA 180 and adjusting the vacuum level to that of the intermediate space of the reaction chamber element 160. The substrate heating may be accelerated with a flow of air with help of e.g. a fan, thermal radiation and/or cycled pressure. In an embodiment, at the time of transferring the substrates into the reaction chamber element 160, the substrates are in the same temperature as in the reaction chamber element 160.

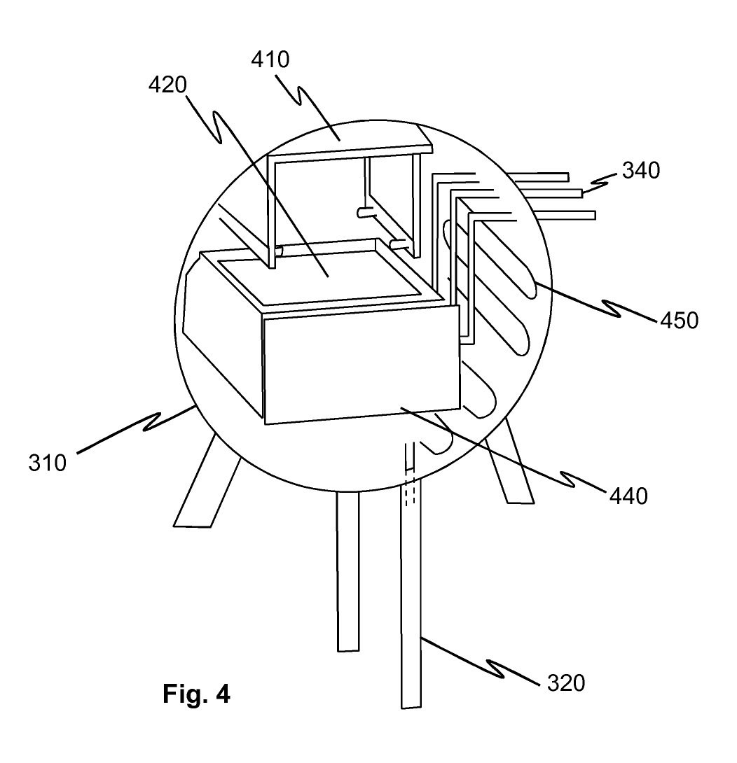

According to an embodiment, the moisture level of out-coming gases from the reaction chamber element 160 (or reaction chamber 420, FIG. 4) is measured by the RGA 180 comprised by the system. This received information (moisture level) in an embodiment is used to control the on-set of atomic layer deposition by the control element 130.

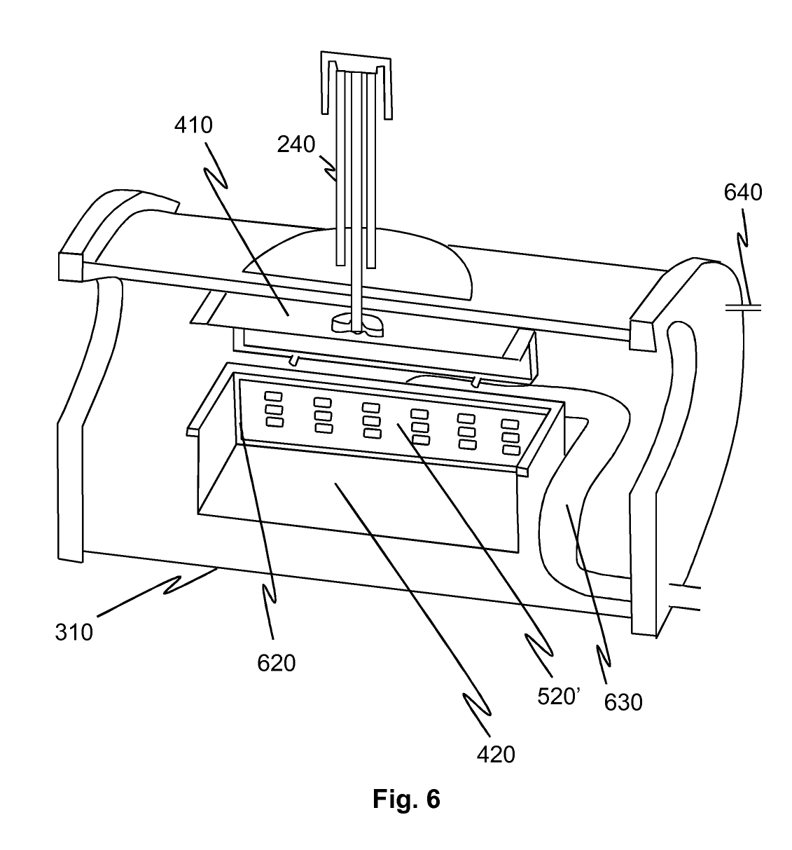

In an embodiment, the control element 130 connected to the RGA 180 controls the starting point of a precursor pulse based on information received from the RGA 180. The RGA 180 measures for example the moisture level of reaction chamber exhaust gases and/or the amount of reaction products or by-product coming out from the reaction chamber 420. The RGA 180 is connected to the exhaust of the reaction chamber 420, and/or foreline 630 (FIG. 6).

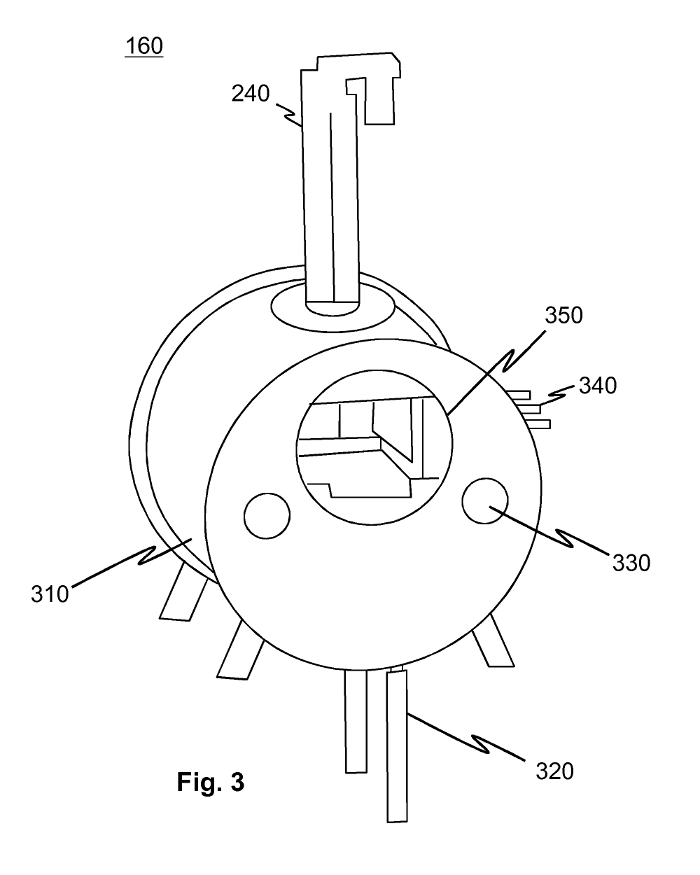

FIG. 3 shows a schematic view of a reaction chamber element 160 of an Atomic Layer Deposition (ALD) system according to an embodiment of the invention. The reaction chamber element 160 comprising a vacuum chamber 310 has an inner part known as intermediate space, kept in vacuum during operation, loading and unloading. In an embodiment, the vacuum chamber 310 comprises a single piece vacuum chamber, i.e., there is no separate outer body for the vacuum chamber and the reaction chamber. In another embodiment, there is more than one reaction chamber. In a further embodiment, the substrate lifting in between the multiple chambers inside the vacuum chamber 310, or further reaction chamber elements, is in an embodiment carried out with actuators 210, 270.

The reaction chamber element 160 comprises the vertical actuator 240 configured to transfer a cassette of substrates in a vertical direction inside the vacuum chamber 310. The same or different actuator is used to close the reaction chamber lid from the intermediate space.

The reaction chamber element, in an embodiment, further comprises actuator elements for raising a shield element in front of a loading opening 350 connected to the second loading valve 250. It is to be understood that the other end of the vacuum chamber 310 comprises a similar opening for connecting to the first loading valve 230 and similar actuator elements for raising a shield element in front of the opening.

The vacuum chamber 310, in an embodiment, further comprises one or more observation windows 330 configured to provide a view or adapting sensors into the vacuum chamber 310 and feedthroughs 340 for connecting to the non-heated or heated sources in the heated source element 170 or non-heated sources in the source element 140. In an embodiment, the feedthroughs 340 connect the source(s) of the source element 170 and separate feedthroughs passing through a bottom wall part of the vacuum chamber 310 (not shown in FIG. 4) connect the source(s) of the source element 140. Both the feedthroughs 340 passing, in an embodiment, through a side wall part of the vacuum chamber 310 and the feedthroughs (not shown) from the source element 140 and passing, in an embodiment, through the bottom wall part of the vacuum chamber 310 lead into an inlet of the reaction chamber 420 (FIG. 4).

FIG. 4 shows a schematic view into a reaction chamber element 160 of an Atomic Layer Deposition (ALD) system according to an embodiment of the invention. The vacuum chamber 310 comprises a reaction chamber 420, in an embodiment at the lower part of the vacuum chamber 310, the remainder of the internal space within the vacuum chamber forming the intermediate space. The vacuum chamber 310 further comprises a cassette holder lid 410 connected to the vertical actuator and configured to be lowered on top of the reaction chamber 420 in order to close it. The cassette holder 410 lid thereby also forms a reaction chamber lid.

The cassette holder lid 410 is configured to receive the loaded cassette and to lower the cassette into the reaction chamber 420. The lowering of the cassette holder lid/reaction chamber lid 410 on the reaction chamber results on an advantage compared to moving substrates upwards. As the substrates are pooling the lid down by their own weight, there is no need for additional, external force. Possible displacements caused by thermal expansion from outside of the reaction chamber become irrelevant. This prevents abrasion in between the reaction chamber 420 edge and the lid 410 and thus particle formation, which could occur due to minor thermal and pressure changes.

The vacuum chamber 310 further comprises a shield element 440 configured to be moved from front of the loading opening, for example lowered, when loading the chamber and to be moved, for example raised, in front of the loading opening using the actuators 320. The shield element comprises in an embodiment a metal plate configured to prevent heat from the intermediate space heating the load-lock of that side, i.e. the shield element is configured to function as a heat reflector. In an embodiment, the shield element 440 comprises a stack of metal plates. It is understood that the other end of the vacuum chamber comprises a similar shield element 440.

In an embodiment, the actuation of the shield element 440 and the opening and closing of the gate valves 230, 250 and/or lid 410 is synchronized and/or integrated with common actuators to carry out both tasks.

The vacuum chamber 310 further comprises heaters 450, in an embodiment radiation heaters, in the intermediate space, on the inner surface of the chamber 310 configured to maintain the vacuum chamber 310 and the reaction chamber 420 in a desired temperature. In an embodiment, the heaters are outside of the vacuum chamber 310, and thus the vacuum chamber 310 wall will conduct the heat to the interior part.

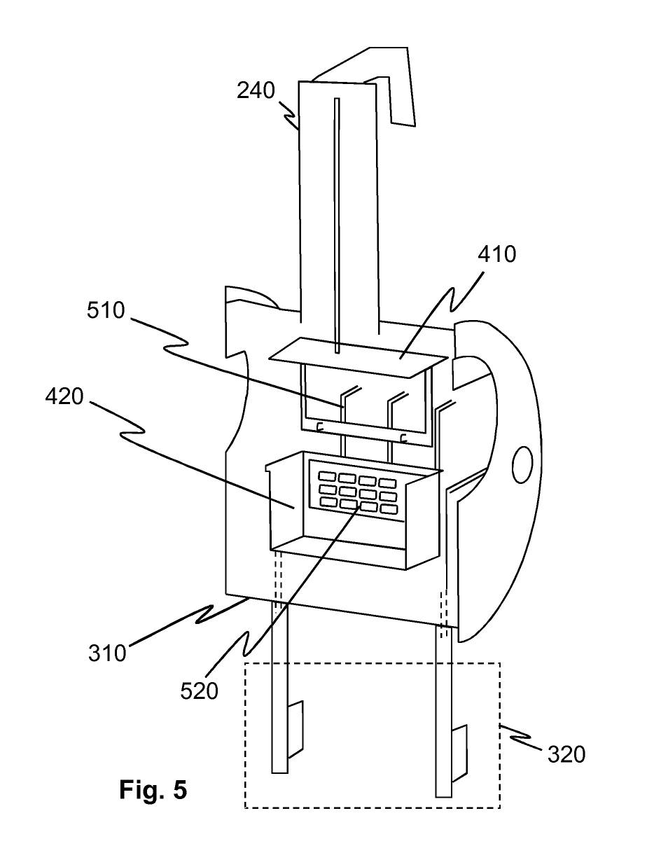

FIG. 5 shows a schematic view into a reaction chamber element 160 of an Atomic Layer Deposition (ALD) system according to an embodiment of the invention. The vacuum chamber 310 comprises source inlet lines 510 connected to the heated source element 170 or to the source element 140. The source inlet lines 510 are configured to travel some distance inside the vacuum chamber so as to stabilize the temperature thereof, and accordingly the temperature of the precursor chemicals therein, prior to entering the reaction chamber 420. The reaction chamber 420 comprises on the inlet side thereof a flow guide element 520 configured to be positioned between the substrates to be coated and the incoming gases from the source lines 510. The flow guide element is, in an embodiment, a removable flow guide element. The flow guide element, in an embodiment, comprises a plurality of apertures. The flow guide element, in an embodiment, is a mesh or perforated plate, or similar.

FIG. 6 shows a schematic view into a reaction chamber element 160 of an Atomic Layer Deposition (ALD) system according to an embodiment of the invention. The reaction chamber 420 in an embodiment comprises a fixed or removable frame 620, and in an embodiment comprises a second flow guide element 520′ (also the flow guide element 520 on the inlet side may be installed in a fixed or removable frame). The second flow guide element 520′ is, in an embodiment, a removable flow guide element. The flow guide element 520′, in an embodiment, comprises a plurality of apertures. The flow guide element 520′, in an embodiment, is a mesh or perforated plate, or similar. However, the apertures in the second flow guide element 520′, in an embodiment, differ in number and/or shape and/or size compared to those of the flow guide element 520.

The vacuum chamber 310 comprises a vacuum or exhaust line, hereinafter denoted as foreline 630 connected to a pump (not shown) configured to evacuate the vacuum chamber 310 and in an embodiment to the particle trap 190. The foreline 630 in an embodiment travels some distance inside the vacuum chamber 310 in order to lessen the heat loss therethrough, i.e., the foreline 630 inside the intermediate space is kept at the same temperature as the vacuum chamber 310. The vacuum chamber 310 further comprises feedthroughs 640 for the heater elements. The intermediate space is further connected to the same or different foreline 630 via a different route or routes, such as 640.

In an embodiment, the foreline 630 is connected directly to the particle trap 190 or a pump, in order to further decrease the pressure and/or change the gas flow behavior in the reaction chamber.

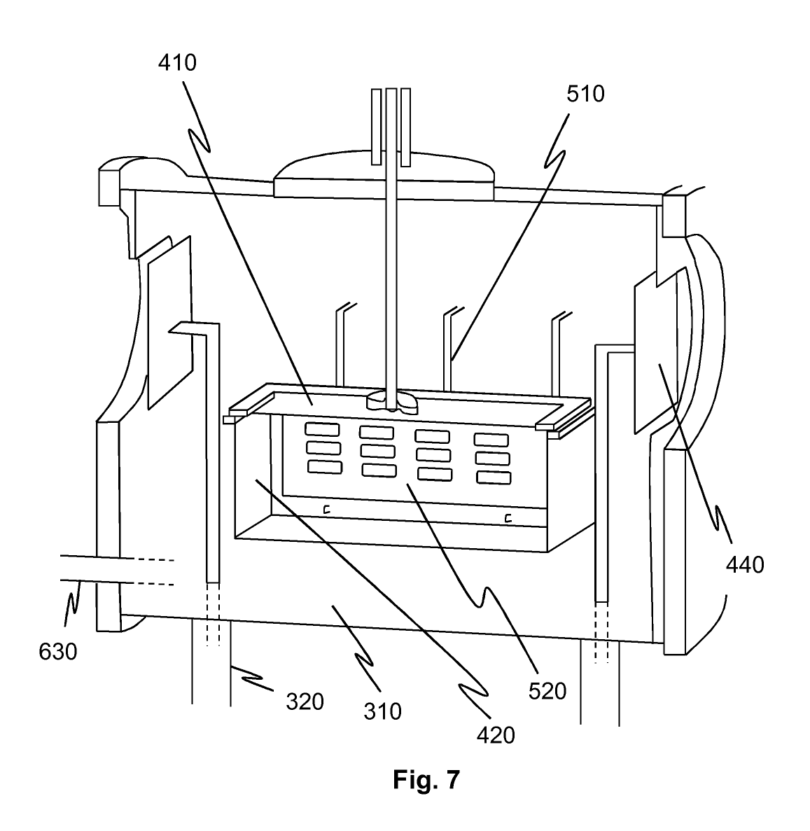

FIG. 7 shows a schematic view into a reaction chamber element 160 of an Atomic Layer Deposition (ALD) system according to an embodiment of the invention. FIG. 7 shows the reaction chamber 420 in closed configuration, i.e., the lid 410 has been lowered on the reaction chamber 420 in order to close the reaction chamber 420 from the intermediate space. The same closing action in an embodiment lowers the substrates to be coated into the reaction chamber. FIG. 7 further shows the shield elements 440 in a closed position, i.e., raised in front of the load openings.

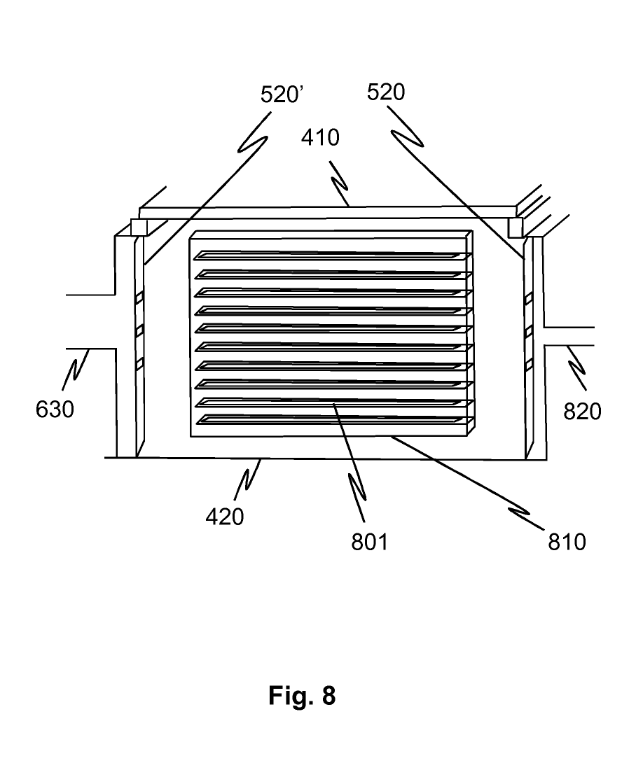

FIG. 8 shows a schematic side view of a reaction chamber 420 of an Atomic Layer Deposition (ALD) system according to an embodiment of the invention. FIG. 8 further shows a cassette 810 loaded in the reaction chamber. The cassette 810 comprises a batch of substrates 801 to be processed. The substrates 801 are placed in the cassette horizontally, thus allowing processing of thin and/or flexible substrates. In an embodiment, the substrates 801 are alternatively placed vertically. In yet another embodiment, a substrate is loaded into the reaction chamber without a cassette or substrate holder. In such an embodiment, the actuator arrangement takes a grip on the substrate and loads it.

FIG. 8 shows the inlet side of the reaction chamber with gas inlet arrangement 820, the (first) flow guide element 520, and the vacuum (or exhaust) side of the reaction chamber with the second flow guide element 520′ and the foreline 630. The gas inlet arrangement 820 and the foreline 630 are arranged in such a way that a horizontal flow of precursor gases is provided.

In an example coating process, the intermediate space is maintained at constant pressure of 20-5 hPa, by controlling the incoming and outgoing gas flows. In an embodiment, the intermediate space is maintained at constant pressure, by controlling the outgoing gas flow. In an advantageous embodiment, there is usually some gas leaving the intermediate space through routes other than through the reaction chamber 420 and the foreline 630. The reaction chamber 420 is operated in pressures and temperatures required by the chemical processes used and the substrates to be processed. The pressure is usually between 10-0.1 hPa, but in some cases down to 0.001 hPa. In an advantageous embodiment, the intermediate space has a higher pressure than the reaction chamber 420, so that the reactive chemicals do not go against the pressure into the intermediate space.

In an embodiment, the substrates to be processed are heated in the load-lock to the temperature used in the reaction chamber, for example 80-160° C., or 30-300° C., depending on the substrates and the process required.

The flow through the gas inlet arrangement 820 to the reaction chamber 420 is adjusted by controlling the volume or mass flow of incoming gas and in an embodiment alternatively or additionally by controlling the foreline pumping with pump parameters. By changing the flow speed of the reactive gas through the substrate cassette, a longer time for reactions to take place is provided as needed. This enables for example positioning of arbitrarily shaped substrates or extremely high aspect ratios of substrates to be coated, for example 2000:1 ratio of depth and width. The control of flows in an embodiment comprises measurement of pressures relevant to the reaction chamber, intermediate space, gas inlet lines and foreline 630.

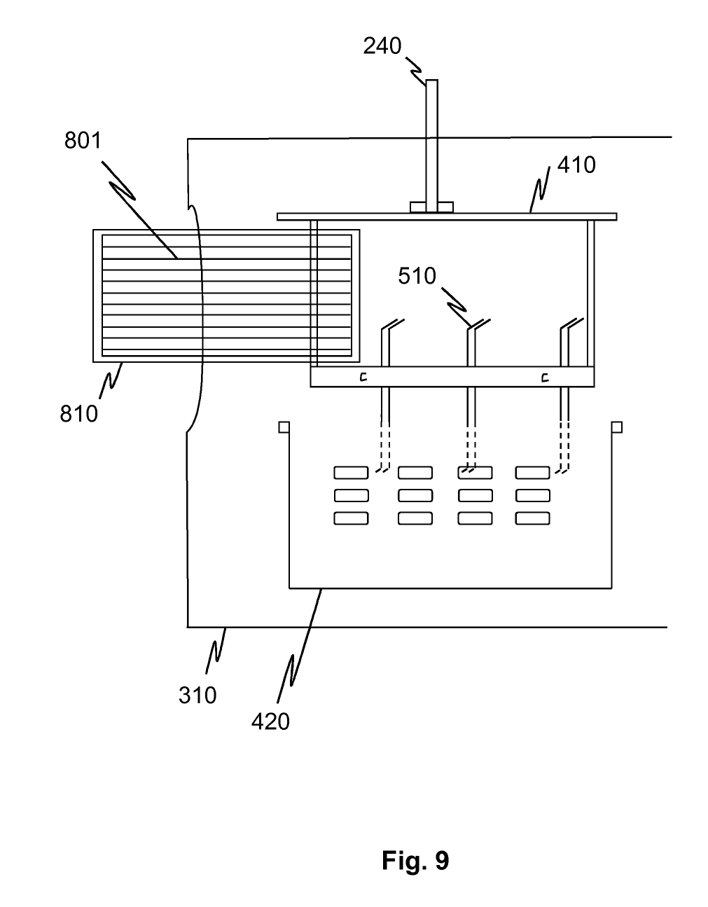

FIG. 9 shows a schematic principle view of loading substrates in a cassette to a reaction chamber element of an Atomic Layer Deposition (ALD) system according to an embodiment of the invention. The cassette 810 is being transferred horizontally from a first load-lock through the first loading valve into the vacuum chamber to be picked up by the lid and the cassette holder attached thereto (i.e., cassette holder lid 410) and then to be lowered vertically by the vertical actuator 240 into the reaction chamber 420.

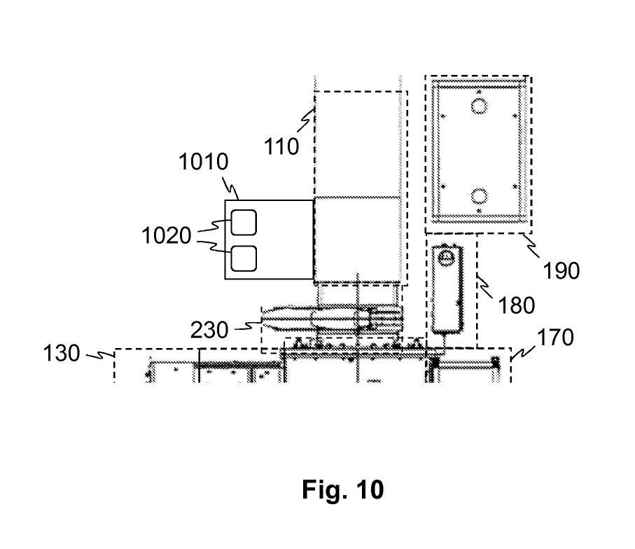

FIG. 10 shows a schematic top view of an Atomic Layer Deposition (ALD) system according to an embodiment of the invention comprising a different cassette element. In this embodiment, the cassette element 120 is replaced by a loading module 1010, such as an equipment front end module (EFEM). The loading module 1010 is located on one or both sides of the load-lock element 110. The loading module 1010 as depicted in FIG. 10 is, in an embodiment, adapted for loading planar substrates, such as wafers. The substrates may reside in standard units 1020, such as front opening uniform pods (FOUP). The loading module 1010 transfers the substrates from the standard units 1020 into the load-lock element 110. The loading module 1010 transfers multiple substrates simultaneously to a horizontal or vertical stack or stacks. It may transfer the substrates individually or as a stack. Rotation of the substrate(s) can be carried out with a loading robot or similar, if rotation is needed. The transfer of substrate(s) into the load-lock is an automated process performed without human interaction.

In yet further embodiments, the precursor chemicals are fed into the reaction chamber 420 via channels in the reaction chamber lid 410. In this embodiment the gas inlet arrangement 820 is adapted to feed the reaction chemicals to the lid 410 and the distributor plate (flow guide element) 520 is positioned horizontally over the substrates. In this embodiment, the foreline 630 is located at the bottom of the reaction chamber 420.

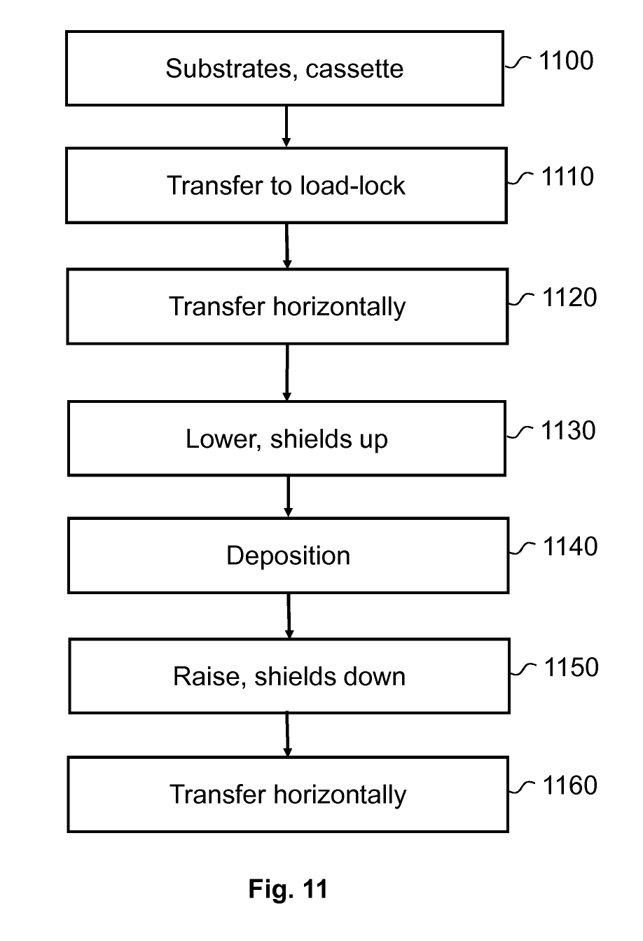

FIG. 11 shows a flow chart of a method of operating an Atomic Layer Deposition (ALD) system according to an embodiment of the invention. At step 1100 a batch of substrates to be processed are loaded horizontally into the cassette 810 which is loaded into the first load-lock 110 at step 1110 using the cassette element 120. At step 1120 the cassette 810 is transferred horizontally into the vacuum chamber 310 using the first horizontal actuator 210 and picked up by the lid 420 connected to the vertical actuator 240. At step 1130 the cassette is lowered into the reaction chamber 420 and the shield elements 440 are moved, in an embodiment raised, in front of the loading openings. At step 1140 the Atomic Layer Deposition is carried out in the reaction chamber 420. At step 1150 the cassette 810 is raised from the reaction chamber 420 and the shield elements 440 are moved, in an embodiment lowered, from front of the loading openings. At step 1160, the cassette is picked up by the first 210 or the second 270 horizontal actuator and transferred into the first 220 or second 260 load-lock. In an embodiment with multiple reaction chambers, all reaction chambers are loaded in a similar manner from the load-lock 210.

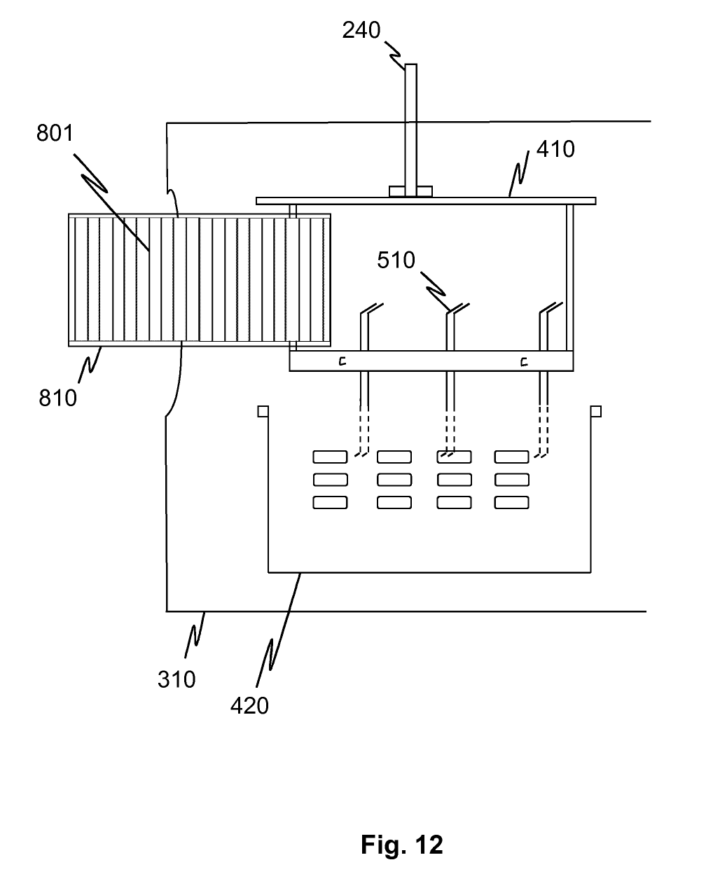

FIG. 12 shows a schematic principle view of loading a reaction chamber element of an Atomic Layer Deposition (ALD) system according to an alternative embodiment of the invention. In this embodiment, the substrates are vertically oriented in the holder 801 to form a horizontal stack of vertically oriented substrates. The operation of this embodiment otherwise corresponds to that of FIG. 9. The flow of precursor gases is in parallel with the substrate surfaces so the flow direction is from “back-to-front” in FIG. 12.

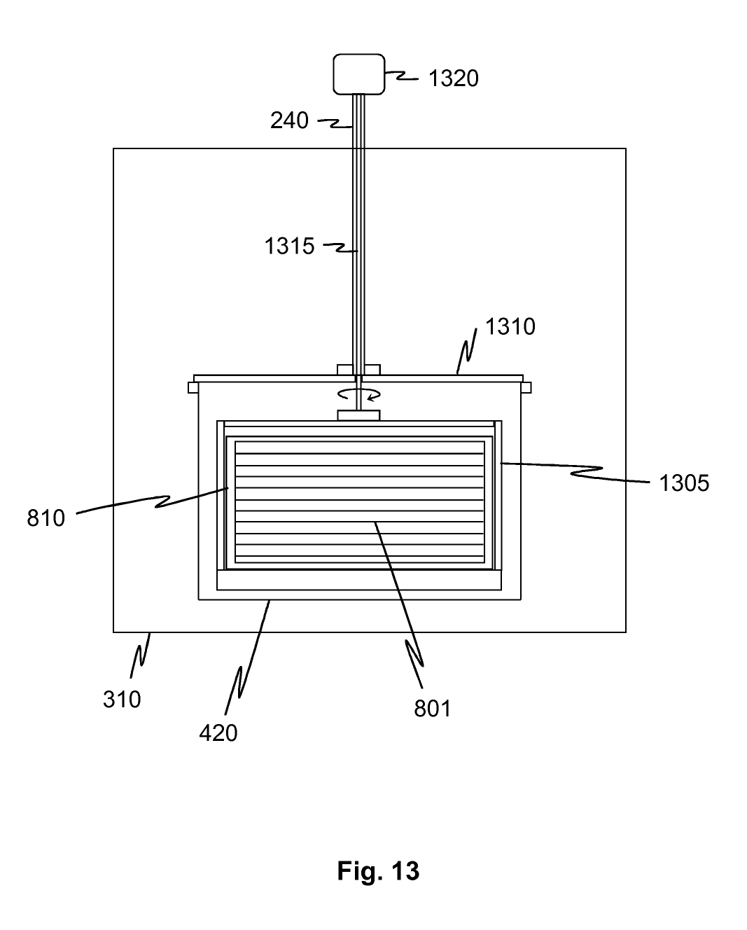

FIG. 13 shows a schematic view into a reaction chamber element of an Atomic Layer Deposition (ALD) system according to yet another embodiment of the invention. In this embodiment, the substrates 801 with the cassette 810 are carried by a rotating cassette holder through the lid 1310. A holder part 1305 holding the substrates 801 (or cassette 810) is rotatable by a motor 1320 integrated to the vertical actuator 240. A rotator shaft 1315 extends inside of the vertical actuator 240 from the motor 1320 from the outside of the vacuum chamber 310 to the rotatable holder part 1305 inside the reaction chamber 420. In an alternative embodiment, the rotation of the substrates from motor 1320, via shaft, is arranged from the bottom, through the bottom of the reaction chamber 420 independently of the elevation actuator 240. In a yet alternative embodiment, the rotation of the substrates from motor 1320, via shaft, is arranged from the side, through the side wall of the reaction chamber 240.

In yet further embodiments, a sensitive substrate such as a glass, silicon, PCB or polymer substrate, or a batch of sensitive substrates, is processed. The reaction chamber 420 is provided inside the vacuum chamber 310, and atomic layer deposition is carried out on the sensitive substrate or the batch of sensitive substrates in the reaction chamber 420. After the deposition (ALD), the sensitive substrate is transferred or the batch of sensitive substrates are transferred via the vacuum chamber 310 to a load lock 220 or 260 connected to the vacuum chamber. The sensitive substrate is cooled or the batch of sensitive substrates are cooled in vacuum within the load lock. By cooling the sensitive substrate(s) in vacuum the risk of breaking the substrate(s) is significantly lower.

Without limiting the scope and interpretation of the patent claims, certain technical effects of one or more of the example embodiments disclosed herein are listed in the following. A technical effect is the enabling of simultaneous degassing and/or heating, ALD processing, including the possibility of adjusting the vacuum levels in between the intermediate space and the reaction chamber, and temperature stabilization of the substrates in the reaction chamber, and cooling down including adjusting the unloading pressure. Another technical effect is allowing processing of sensitive, such as flexible, substrates laid horizontally with minimum stress. A further technical effect is loading the substrates for deposition without flipping. A still further technical effect is lower height of the system due to the vacuum chamber structure providing ease of loading and handling of the substrates on human hand height, with horizontal movement to the reactor. A still further technical effect is allowing lowering the lid with substrates on the reaction chamber vertically so that there will not be moving, possibly hot, metal-to-metal interfaces that could possibly create particles, and which interfaces separate the intermediate pressure from the reaction chamber pressure and gases. A still further technical effect is improved temperature control with shield elements and the long vacuum line running inside the vacuum chamber. A still further technical effect is ease of maintenance due to the modular structure also enabling an assembly which consists of several reaction chambers in a row, possibly separated by further gate valve elements. A still further technical effect is minimizing particle creation with the vertical lid movement. A still further technical effect is the assembly with several reaction chambers inside the vacuum chamber element, in the same or different intermediate space so that one chamber can be loaded or unloaded independent of the operation in the other chamber.

It should be noted that some of the functions or method steps discussed in the preceding may be performed in a different order and/or concurrently with each other. Furthermore, one or more of the above-described functions or method steps may be optional or may be combined.

The foregoing description has provided by way of non-limiting examples of particular implementations and embodiments of the invention a full and informative description of the best mode presently contemplated by the inventors for carrying out the invention. It is however clear to a person skilled in the art that the invention is not restricted to details of the embodiments presented above, but that it can be implemented in other embodiments using equivalent means without deviating from the characteristics of the invention.

Furthermore, some of the features of the above-disclosed embodiments of this present disclosure may be used to advantage without the corresponding use of other features. As such, the foregoing description should be considered as merely illustrative of the principles of the present invention, and not in limitation thereof. Hence, the scope of the present disclosure is only restricted by the appended patent claims.

1. A system for atomic layer deposition, ALD, comprising:
a reaction chamber element comprising
a vacuum chamber;
a reaction chamber inside the vacuum chamber; and
a gas inlet arrangement and a foreline configured to provide a horizontal flow of gas in the reaction chamber;
an actuator arrangement comprising a reaction chamber lid, and
at least a first load-lock element comprising a first load-lock,
the actuator arrangement being configured to receive a substrate or a batch of substrates to be processed and transfer the substrate or the batch of substrates through the first load-lock horizontally into the vacuum chamber,
the actuator arrangement being further configured to lower the substrate or the batch of substrates within the vacuum chamber into the reaction chamber thus closing the reaction chamber with the lid.

2. The system of claim 1, wherein the actuator arrangement comprises a first horizontal actuator in the first load-lock element and a vertical actuator in the reaction chamber element, the first horizontal actuator being configured to receive the substrate or the batch of substrates and transfer the substrate or the batch of substrates through the first load-lock horizontally into the vacuum chamber, and the vertical actuator being configured to receive the substrate or the batch of substrates from the first horizontal actuator and lower the substrate or the batch of substrates into the reaction chamber.

3. The system of claim 1, further comprising a second load-lock element comprising a second load-lock.

4. The system of claim 1, further comprising a first loading valve between the first load-lock and a loading opening of the vacuum chamber.

5. The system of claim 3, further comprising a first loading valve between the first load-lock and a loading opening of the vacuum chamber and a second loading valve between the second load-lock and a loading opening of the vacuum chamber.

6. The system of claim 3, wherein the actuator arrangement comprises a second horizontal actuator in the second load-lock element.

7. The system of claim 1, wherein the vacuum chamber comprises at least one shield element configured to be moved in front of at least one loading opening of the vacuum chamber.

8. The system of claim 7, wherein the at least one shield element is configured to be moved with actuators and/or in synchronization with the opening and closing of the loading valves.

9. The system of claim 1, further comprising at least one residual gas analyzer element comprising a residual gas analyzer, RGA, and connected to the first and/or second load-lock element and/or foreline.

10. The system of claim 1, wherein the foreline travels inside the vacuum chamber.

11. The system of claim 1, wherein the reaction chamber comprises at least one removable flow guide element.

12. The system of claim 1, further comprising a heated source element connected to the reaction chamber element.

13. The system of claim 1, wherein the vacuum chamber comprises source inlets traveling inside the vacuum chamber.

14. The system of claim 1, further comprising a cassette for holding the substrate or the batch of substrates to be processed.

15. The system claim 1, comprising a rotator configured to rotate the substrate or the batch of substrates within the reaction chamber.

16. The system of claim 1, further comprising a loading module, such as an equipment front end module, and/or a loading robot connected to the first load-lock element.

17. The system of claim 1, wherein the system is configured to heat or cool the substrate or batch of substrates in at least one of the first and second load lock element.

18. The system of claim 1, wherein the system is configured to pump down the load-lock pressure below the pressure used in the reaction chamber.

19. The system of claim 1, wherein the system is configured to measure gases coming from the substrate or the batch of substrates in the load-lock.

20. A method of operating a system for atomic layer deposition, ALD, comprising:
transferring a substrate or a batch of substrates into a first load-lock;
transferring the substrate or the batch of substrates further from the first load-lock via a first loading valve and a loading opening horizontally into a vacuum chamber;
receiving the substrate or the batch of substrates in the vacuum chamber and lowering the substrate or the batch of substrates into a reaction chamber inside the vacuum chamber, the act of lowering closing the reaction chamber with a lid;
carrying out atomic layer deposition in the reaction chamber;
raising the substrate or the batch of substrates from the reaction chamber;
receiving the substrate or the batch of substrates from the reaction chamber and transferring the substrate or the batch of substrates via the first or a second loading valve and a loading opening from the vacuum chamber into the first or a second load-lock.

21. The method of claim 20, further comprising moving at least one shield element in front of the at least one load opening, respectively, before the atomic layer deposition; and removing the at least one shield element from front of the at least one load opening, respectively, after the atomic layer deposition.

22. The method of claim 20, comprising carrying the substrate or batch of substrates in a cassette (810) within the system.

23. The method of claim 20, wherein the pressure or flow speed of the gas or gases in the reaction chamber is adjusted by controlling of incoming gas flow and/or outgoing gas flow in foreline.

24. A method of operating a system for atomic layer deposition, ALD, comprising:
providing a shield element on the outside of a reaction chamber but on the inside of a vacuum chamber;
moving the shield element within the vacuum chamber in front of a loading opening of the vacuum chamber; and
carrying out atomic layer deposition in the reaction chamber inside the vacuum chamber.

25. An apparatus for atomic layer deposition, ALD, comprising:
a reaction chamber inside a vacuum chamber; and
a shield element on the outside of a reaction chamber but on the inside of the vacuum chamber, the apparatus being configured to
move the shield element within the vacuum chamber in front of a loading opening of the vacuum chamber; and
carry out atomic layer deposition in the reaction chamber inside the vacuum chamber.

26. A method of operating a system for atomic layer deposition, ALD, comprising:
providing a reaction chamber inside a vacuum chamber, and a foreline leading from the reaction chamber to the outside of the vacuum chamber, the method comprising:
maintaining heat within the foreline by allowing the foreline to take a detour within the vacuum chamber on its way to the outside of the vacuum chamber.

27. An apparatus for atomic layer deposition, ALD, comprising:
a reaction chamber inside a vacuum chamber; and
a foreline taking a detour on its way from the reaction chamber to the outside of the vacuum chamber.

28. A method of operating a system for atomic layer deposition, ALD, comprising:
providing a reaction chamber inside a vacuum chamber;
carrying out atomic layer deposition on a sensitive substrate or a batch of sensitive substrates in the reaction chamber;
transferring, after the deposition, the substrate or a batch of sensitive substrates via the vacuum chamber to a load lock connected to the vacuum chamber; and
cooling the sensitive substrate or a batch of sensitive substrates within the load lock in vacuum.

29. An apparatus for atomic layer deposition, ALD, comprising:
a reaction chamber element comprising a reaction chamber inside a vacuum chamber;
a foreline connected to the reaction chamber and configured to lead gases out from the reaction chamber;
a residual gas analyzer connected to the foreline; and
a control element connected to the reaction chamber element and to the residual gas analyzer, wherein
the control element is configured to control process timing by received information measured by the residual gas analyzer.
